(19) United States
(12) Patent Application Publication
(10) Pub. No.: US 2019/0204657 A1
(43) Pub. Date: Jul. 4, 2019

(54) DISPLAY SUBSTRATE AND MANUFACTURING METHOD THEREOF, DISPLAY DEVICE AND MANUFACTURING METHOD THEREOF, AND MOBILE TERMINAL

(71) Applicants: BOE TECHNOLOGY GROUP CO., LTD., Beijing (CN); BOE (Hebei) Mobile Display Technology Co., Ltd., Hebei (CN)

(72) Inventors: Binbin HU, Beijing (CN); He XU, Beijing (CN); Donglai GAO, Beijing (CN); Yu GENG, Beijing (CN); Wenbo WANG, Beijing (CN); Mingtao ZHU, Beijing (CN); Gang HAO, Beijing (CN); Guosong NAN, Beijing (CN)

(21) Appl. No.: 16/128,392

(22) Filed: Sep. 11, 2018

(30) Foreign Application Priority Data
Jan. 2, 2018 (CN) 201810002307.3

(51) Int. Cl. G02F 1/1333; G02F 1/1345; H01L 51/52; G02F 1/1335; H01L 27/32; H01L 51/56; H01L 51/00

(52) U.S. Cl. CPC G02F 1/133305; G02F 1/13454; H01L 51/524; G02F 1/133528; H01L 27/3276; G02F 1/1336; G02F 1/133308; H01L 51/0097; H01L 51/5281; G02F 1/133514; G02F 1/133512; H01L 51/56

(57) ABSTRACT

A display substrate includes a rigid substrate, a flexible substrate, a pixel structure, and bonding terminals. The rigid substrate includes a portion corresponding to a display region of the display substrate. The flexible substrate is disposed on the rigid substrate, and includes a portion corresponding to the display region and a portion corresponding to a bonding region of the display substrate. The pixel structure is disposed in a region on the flexible substrate corresponding to the display region. The bonding terminals are disposed in a region one the flexible substrate corresponding to the bonding region. The portion of the flexible substrate corresponding to the bonding region is bendable.

### CROSS-REFERENCE TO RELATED APPLICATION

This application claims priority to Chinese Patent Application No. 201810002307.3, filed on Jan. 2, 2018, titled “DISPLAY SUBSTRATE AND MANUFACTURING METHOD THEREOF, DISPLAY DEVICE AND MANUFACTURING METHOD THEREOF, AND MOBILE TERMINAL”, which is incorporated herein by reference in its entirety.

### TECHNICAL FIELD

The present disclosure relates to the field of display technologies, and more particularly, to a display substrate and a manufacturing method thereof, a display device and a manufacturing method thereof, and a mobile terminal.

### BACKGROUND

As a device for displaying a picture, the display device can be used to display text, numbers, symbols, pictures, or can be used to display an image formed by combining at least two of words, numbers, symbols, and pictures. The display device is a necessary part for mobile terminals (such as mobile phones and tablet computers).

### SUMMARY

In an aspect, a display substrate is provided. The display substrate includes: a rigid substrate including a portion corresponding to a display region of the display substrate; a flexible substrate disposed on the rigid substrate and including a portion corresponding to the display region of the display substrate and a portion corresponding to a bonding region of the display substrate, wherein, the portion of the flexible substrate corresponding to the bonding region is bendable; a pixel structure disposed in a region on the flexible substrate corresponding to the display region of the display substrate; and bonding terminals disposed in a region on the flexible substrate corresponding to the bonding region of the display substrate.

In some embodiments, the display substrate further includes an opposite substrate disposed on a side of the pixel structure facing away from the flexible substrate, wherein the opposite substrate includes a portion corresponding to the display region of the display substrate.

In some embodiments, the display substrate further includes a first polarizer disposed on a side of the rigid substrate facing away from the flexible substrate, and a second polarizer disposed on a side of the opposite substrate facing away from the flexible substrate.

In some embodiments, the display substrate further includes a circuit board bonded to one of the bonding terminals, and a driving chip bonded to another one of the bonding terminals.

In another aspect, a method for manufacturing the display substrate in the above aspect is provided, and the method includes:

providing an initial rigid substrate, wherein the initial rigid substrate includes a portion corresponding to a display region of the display substrate and a portion corresponding to a bonding region of the display substrate;

forming a flexible substrate on the initial rigid substrate, wherein the flexible substrate includes a portion corresponding to the display region of the display substrate and a portion corresponding to the bonding region of the display substrate, and the portion of the flexible substrate corresponding to the bonding region is bendable;

forming a pixel structure and bonding terminals on the flexible substrate, wherein the pixel structure is disposed in the display region, and the bonding terminals are disposed in the bonding region; and

removing the portion of the initial rigid substrate corresponding to the bonding region of the display substrate, wherein a remaining portion of the initial rigid substrate after the portion of the initial rigid substrate corresponding to the bonding region of the display substrate is removed forms a rigid substrate of the display substrate.

In some embodiments, providing the initially rigid substrate includes:

providing an entire rigid substrate, wherein the entire rigid substrate includes a portion corresponding to the display region of the display substrate and a portion corresponding to the bonding region of the display substrate; and

forming a cutting line between the portion of the entire rigid substrate corresponding to the display region and the portion of the entire rigid substrate corresponding to the bonding region, so as to form the initial rigid substrate, wherein the cutting line is formed by cutting from a side of the initial rigid substrate facing away from the flexible substrate, and the portion of the entire rigid substrate corresponding to the display region and the portion of the entire rigid substrate corresponding to the bonding region are partially connected.

In some embodiments, before removing the portion of the initial rigid substrate corresponding to the bonding region of the display substrate, the method for manufacturing the display substrate further includes:

providing an opposite substrate, wherein the opposite substrate includes a portion corresponding to the display region of the display substrate, and

assembling the opposite substrate with the initial rigid substrate on which the flexible substrate, the pixel structure, and the bonding terminals have been formed.

In some embodiments, before removing the portion of the initial rigid substrate corresponding to the bonding region of the display substrate, and after assembling the opposite substrate with the initial rigid substrate on which the flexible substrate, the pixel structure, and the bonding terminals have been formed, the method for manufacturing the display substrate further includes:

forming a first polarizer on a side of the initial rigid substrate facing away from the flexible substrate, and forming a second polarizer on a side of the opposite substrate facing away from the flexible substrate; and

bonding a circuit board and a driving chip in a region on the flexible substrate corresponding to the bonding region of the display substrate, wherein the circuit board and the driving chip are connected to the bonding terminals respectively.

In another aspect, a display device is provided. The display device includes: the display substrates according to the above aspect; a backlight module disposed on a side of the rigid substrate of the display substrate facing away from the flexible substrate of the display substrate; and a cover plate disposed on a side of the flexible substrate facing away from the rigid substrate.

In another aspect, a method for manufacturing the display device described in the above aspect is provided, and the method includes: applying the method for manufacturing the display substrate described in the above aspect to form a display substrate, and forming a backlight module and a cover plate.

In some embodiments, forming the backlight module and the cover plate is performed before removing the portion of the initial rigid substrate corresponding to the bonding region of the display substrate.

In another aspect, a mobile terminal is provided, and the mobile terminal includes the display devices described in the above aspect; and a housing including a sidewall corresponding to a portion of the flexible substrate of the display substrate in the display device corresponding to the bonding region of the display substrate, wherein the side wall is provided with a groove, and the portion of the flexible substrate corresponding to the bonding region of the display substrate is bent in the groove.

### BRIEF DESCRIPTION OF THE DRAWINGS

In order to describe technical solutions in embodiments of the present disclosure more clearly, the accompanying drawings to be used in the description of embodiments will be introduced briefly. Obviously, the accompanying drawings to be described below are merely some embodiments of the present disclosure, and a person of ordinary skill in the art can obtain other drawings according to those drawings without paying any creative effort.

FIG. 1 is a top view of a display substrate in accordance with some embodiments of the present disclosure;

FIG. 2 is a right side view of the display substrate of FIG. 1;

FIG. 3 is a top view showing a portion of the display substrate of FIG. 1 corresponding to a bonding region after being bent;

FIG. 4 is a schematic flowchart of a method for manufacturing a display substrate in accordance with some embodiments of the present disclosure;

FIG. 5 is a schematic flowchart of another method for manufacturing a display substrate in accordance with some embodiments of the present disclosure;

FIG. 6 is a diagram showing processing steps of a method for manufacturing a display substrate in accordance with some embodiments of the present disclosure;

FIG. 7 is a schematic structural diagram of a display device in accordance with some embodiments of the present disclosure;

FIG. 8 is a schematic flowchart of a method for manufacturing a display device in accordance with some embodiments of the present disclosure;

FIG. 9 is a schematic flowchart of another method for manufacturing a display device in accordance with some embodiments of the present disclosure;

FIG. 10 is a schematic structural diagram of a mobile terminal in accordance with some embodiments of the present disclosure;

FIG. 11 is a section view of the display substrate of FIG. 1; and

FIG. 12 is another section view of the display substrate of FIG. 1.

### DETAILED DESCRIPTION

In order to further illustrate a display substrate and a method for manufacturing the same, a display device and a method for manufacturing the same, and a mobile terminal in accordance with embodiments of the present disclosure, the above contents will be described in detail in conjunction with the accompanying drawings of the specification.

With the development of mobile terminals, high-screen-ratio mobile terminals have become an inevitable trend. The high-screen-ratio mobile terminal is generally restricted by the structure of the display device.

The display device usually includes a display substrate. The display substrate usually includes a display region and a bonding region on a side of the display region. Bonding terminals are provided in the bonding region and are used to bond a driving chip and a circuit board (such as a flexible circuit board). The circuit board and the driving chip are used to drive the pixel structure in the display region to display. In the related art, when the display device is applied to a mobile terminal, the bonding region generally occupies a certain area, and the bonding region cannot be used to display, resulting in a relatively reduced display region of the mobile terminal, i.e., a reduction in the screen-ratio of the mobile terminal.

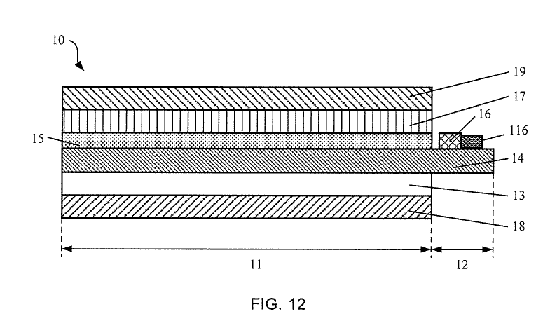

Regarding the problem described above, referring to FIG. 1 to FIG. 3, some embodiments of the present disclosure provide a display substrate 10, and the display substrate 10 includes a display region 11 and a bonding region 12 on a side of the display region 11. As shown in FIGS. 11 and 12, the display region 11 is configured to display a screen, and the bonding region 12 is configured to bond a circuit board 106, a driving chip 116, etc. The circuit board 106 and the driving chip 116 are configured to drive the display region 11 for display. The display substrate 10 includes a rigid substrate 13, a flexible substrate 14, a pixel structure 15, and bonding terminals 16. The rigid substrate 13 includes a portion corresponding to the display region 11 of the display substrate 10. The flexible substrate 14 is disposed on a surface of the rigid substrate 13. The flexible substrate 14 includes a portion corresponding to the display region 11 of the display substrate 10 and a portion corresponding to the bonding region 12 of the display substrate 10. Both the pixel structure 15 and the bonding terminal 16 are disposed on a surface of the flexible substrate 14 facing away from the rigid substrate 13. The pixel structure 15 is disposed in a region on the flexible substrate 14 corresponding to the display region 11 of the display substrate 10. The bonding terminals 16 are disposed in a region on the flexible substrate 14 corresponding to the bonding region 12 of the display substrate 10. The portion of the flexible substrate 14 corresponding to the bonding region 12 is bendable.

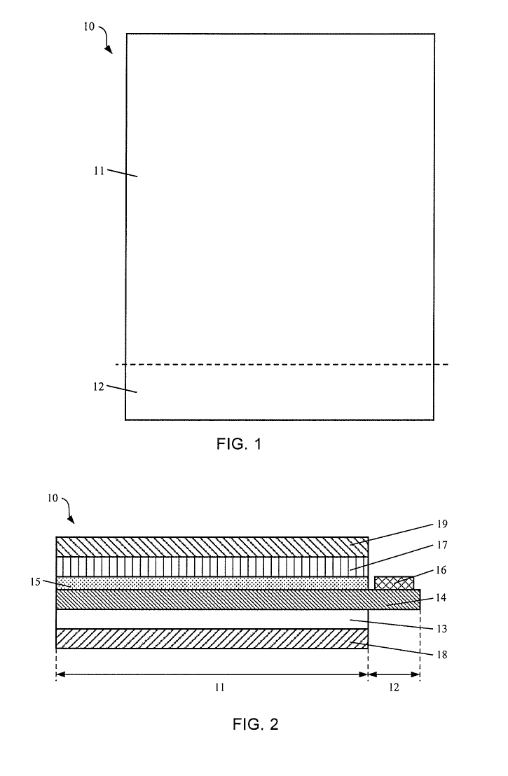

For example, referring again to FIG. 1 and FIG. 2, the display substrate 10 includes a rigid substrate 13, a flexible substrate 14, a pixel structure 15, and bonding terminals 16. The rigid substrate 13 includes a portion corresponding to the display region 11 of the display substrate 10 and does not include a portion corresponding to the bonding region 12 of the display substrate 10. The flexible substrate 14 is disposed on a surface of the rigid substrate 13, and includes a portion corresponding to the display region 11 of the display substrate 10 and a portion corresponding to the bonding region 12 of the display substrate 10. The portion of the flexible substrate 14 corresponding to the display region 11 is combined with the portion of the rigid substrate 13 corresponding to the display region 11, and the rigid substrate 13 is configured to support the portion of the flexible substrate 14 corresponding to the display region 11. The portion of the flexible substrate 14 corresponding to the bonding region 12 is suspended, and is bendable. Both the pixel structure 15 and the bonding terminals 16 are disposed on the flexible substrate 14. The pixel structure 15 is disposed in a region on the flexible substrate 14 corresponding to the display region 11. The bonding terminals 16 are disposed in a region on the flexible substrate 14 corresponding to the bonding region 12. The bonding terminals 16 are connected with the pixel structure 15.

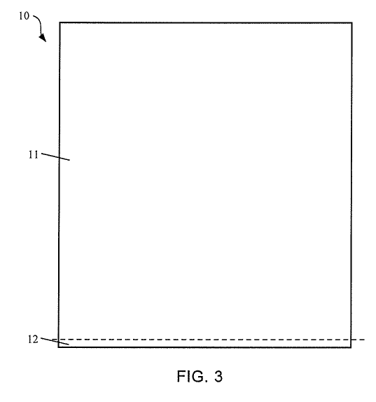

In the display substrate 10 provided by the embodiments of the present disclosure, the pixel structure 15 and the bonding terminals 16 are both disposed on the flexible substrate 14. The pixel structure 15 is disposed in a region on the flexible substrate 14 corresponding to the display region 11, and the bonding terminals 16 are disposed in a region on the flexible substrate 14 corresponding to the bonding region 12. The rigid substrate 13 supports the portion of the flexible substrate 14 corresponding to the display region 11. The portion of the flexible substrate 14 corresponding to the bonding region 12 is bendable, that is, the portion of the flexible substrate 14 on which the bonding terminals 16 are disposed can be bent. After the portion of the flexible substrate 14 corresponding to the bonding region 12 is bent, as shown in FIG. 3, the bonding region 12 no longer occupies a larger planar area on the display substrate 10, so that the planar area of the display substrate 10 is reduced. When the display device provided with the display substrate 10 according to the embodiments of the present disclosure is applied to a mobile terminal, the area of the mobile terminal occupied by the bonding region 12 may be reduced, which prevents the display region of the mobile terminal from being relatively reduced due to the fact that the bonding region 12 which cannot be used for display occupies a larger area of the mobile terminal. Thus, almost full-screen display of the mobile terminal is achieved, and the screen-ratio of the mobile terminal is improved.

In addition, in the display substrate 10, the rigid substrate 13 is configured to support the portion of the flexible substrate 14 corresponding to the display region 11. As a result, it is possible to prevent the portion of the flexible substrate 14 corresponding to display region 11 from being adversely affected, such as being pulled, etc., by the portion of the flexible board 14 corresponding to the bonding region 12 when it is bent. As a result, the quality of the display substrate 10 may be improved.

In some embodiments, the display substrate 10 is a liquid crystal display substrate. Alternatively, in some embodiments, the display substrate 10 is an OLED (Organic Light-Emitting Diode) display substrate.

Referring again to FIG. 2, the display substrate 10 further includes an opposite substrate 17 disposed on a side of the pixel structure 15 facing away from the flexible substrate 14. The opposite substrate 17 includes a portion corresponding to the display region 11 of the display substrate 10.

In some embodiments, the display substrate 10 is a liquid crystal display substrate, and the opposite substrate 17 is a color filter substrate. At this time, in some embodiments, in the display substrate 10, a color filter layer, a black matrix, and a common electrode are included in the opposite substrate 17 (that is the color filter layer, the black matrix, and the common electrode are all disposed on a base substrate of the opposite substrate 17), and the display substrate 10 is for example a TN (Twisted Nematic) display substrate. In some other embodiments, in the display substrate 10, the color filter layer and the black matrix are included in the opposite substrate 17 (that is the color filter layer, the black matrix are both disposed on the base substrate of the opposite substrate 17), and the common electrode is provided on the flexible substrate 14.

In some other embodiments, the opposite substrate 17 is a glass substrate. At this time, in some embodiments, the display substrate 10 is an ADS (Advanced Super Dimension Switch) display substrate, and each functional film layer in the display substrate 10 is formed on the flexible substrate 14, that is, a thin film transistor (TFT) array, a pixel electrodes, a common electrode, a color film layer, a black matrix are all disposed on the flexible substrate 14. In some other embodiments, the display substrate 10 is an OLED display substrate, and the opposite substrate 17 is a packaging cover plate.

With continued reference to FIG. 2, in some embodiments, the display substrate 10 is a liquid crystal display substrate, and the display substrate 10 further includes a first polarizer 18 and a second polarizer 19. The first polarizer 18 is disposed on a side of the rigid substrate 13 facing away from the flexible substrate 14. The second polarizer 19 is disposed on a side of the opposite substrate 17 facing away from the flexible substrate 14. The backlight enters the first polarizer 18, and then polarized light whose polarization direction is parallel to the polarization direction of the first polarizer 18 is obtained. The polarized light enters the second polarizer 19 after passing through the rigid substrate 13, the flexible substrate 14, and the opposite substrate 17. Of the light incident on the second polarizer 19, the light having a polarization direction parallel to the polarization direction of the second polarizer 19 is emitted from the second polarizer 19, and the light having a polarization direction perpendicular to the polarization direction of the second polarizer 19 is blocked by the second polarizer 19. Thus, the display of the display substrate 10 is achieved.

In some embodiments, the display substrate 10 further includes a circuit board 106 and a driving chip 116, which are bonded to the bonding terminals 16 respectively. The circuit board 106 and the driving chip 116 are configured to together provide a display signal for the pixel structure 15 to drive the pixel structure 15 to display so as to realize the display of the display substrate 10.

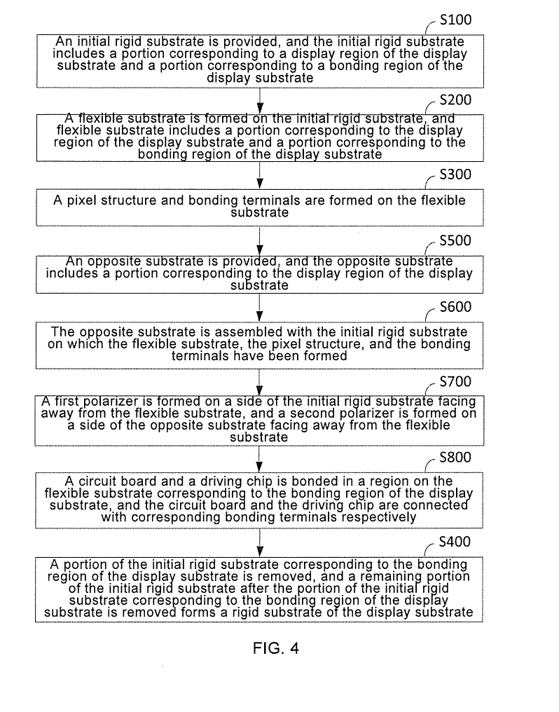

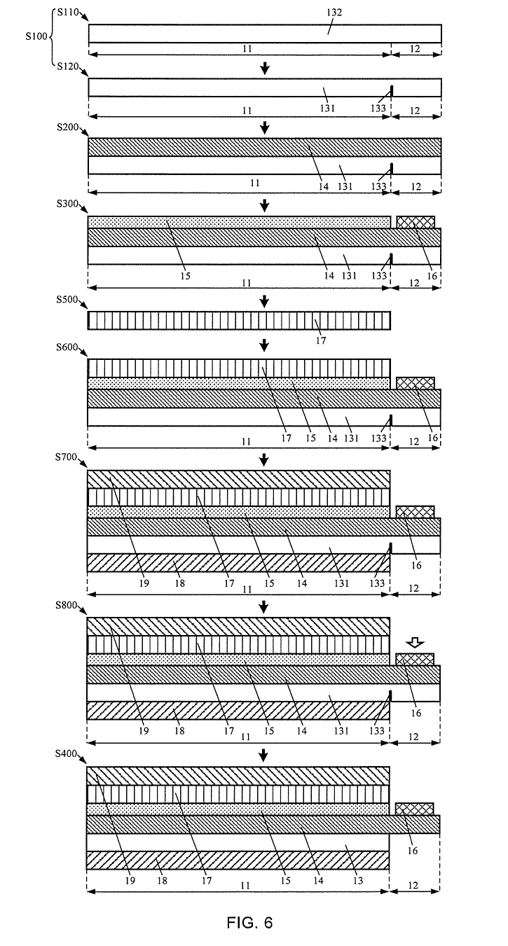

Referring to FIG. 4 and FIG. 6, some embodiments of the present disclosure provide a method for manufacturing a display substrate, and the method is for example applied to manufacture the display substrate described in the above embodiments. The method includes the following steps 100-400 (S100-S400).

In S100, an initial rigid substrate is provided. The initial rigid substrate includes a portion corresponding to a display region of the display substrate and a portion corresponding to a bonding region of the display substrate.

For example, referring to FIG. 6, the initial rigid substrate 131 is for example a glass substrate. The initial rigid substrate 131 includes a portion corresponding to the display region 11 of the display substrate 10 and a portion corresponding to the bonding region 12 of the display substrate 10, in order to subsequently form a flexible substrate 14 on the initial rigid substrate 131.

In S200, a flexible substrate is formed on the initial rigid substrate. The flexible substrate includes a portion corresponding to the display region of the display substrate and a portion corresponding to the bonding region of the display substrate.

For example, referring to FIG. 6, the flexible substrate 14 is formed on the initial rigid substrate 131. The flexible substrate 14 covers the initial rigid substrate 131. In some embodiments, the material of the flexible substrate 14 is an inorganic material, such as silicon oxide (SiOₓ), silicon nitride (SiNₓ), silicon oxynitride (SiON), etc. In some other embodiments, the material of the flexible substrate 14 is an organic material, such as polyimide (PI), etc.

In S300, a pixel structure and bonding terminals are formed on the flexible substrate. The pixel structure is disposed in the display region, and the bonding terminals are disposed in the bonding region.

For example, referring to FIG. 6, a pixel structure 15 and bonding terminals 16 are formed on the flexible substrate 14. The pixel structure 15 is disposed in a region on the flexible substrate 14 corresponding to the display region 11 of the display substrate 10. In some embodiments, the pixel structure 15 includes thin film transistors, pixel electrodes. Alternatively, the pixel structure 15 includes thin film transistors, pixel electrodes, and a common electrode. Alternatively, the pixel structure 15 includes thin film transistors, pixel electrodes, a common electrode, a color film layer, and a black matrix. Alternatively, the pixel structure 15 includes thin film transistors and OWED devices. The bonding terminal 16 is disposed in a region on the flexible substrate 14 corresponding to the bonding region 12 of the display substrate 10. The bonding terminals 16 are connected to the pixel structure 15.

In S400, a portion of the initial rigid substrate corresponding to the bonding region of the display substrate is removed. A remaining portion of the initial rigid substrate after the portion of the initial rigid substrate corresponding to the bonding region of the display substrate is removed forms a rigid substrate of the display substrate, and the portion of the flexible substrate corresponding to the bonding region is bendable.

For example, referring to FIG. 6, the portion of the initial rigid substrate 131 corresponding to the bonding region 12 of the display substrate 10 is removed, and thus a rigid substrate 13 including a portion corresponding to the display region 11 and not including a portion corresponding to the bonding region 12 is formed. In some embodiments, a laser cutting method or an ultrasonic cutting method is used to remove the portion of the initial rigid substrate 131 corresponding to the bonding region 12 of the display substrate 10. After the portion of the initial rigid substrate 131 corresponding to the bonding region 12 of the display substrate 10 is removed, the portion of the flexible substrate 14 corresponding to the bonding region 12 is no longer supported by the rigid substrate 13 and is suspended, and thus can be bent upward or downward.

The method for manufacturing the display substrate has the same advantage as the display substrate described above with respect to the related art, which will not be repeated here.

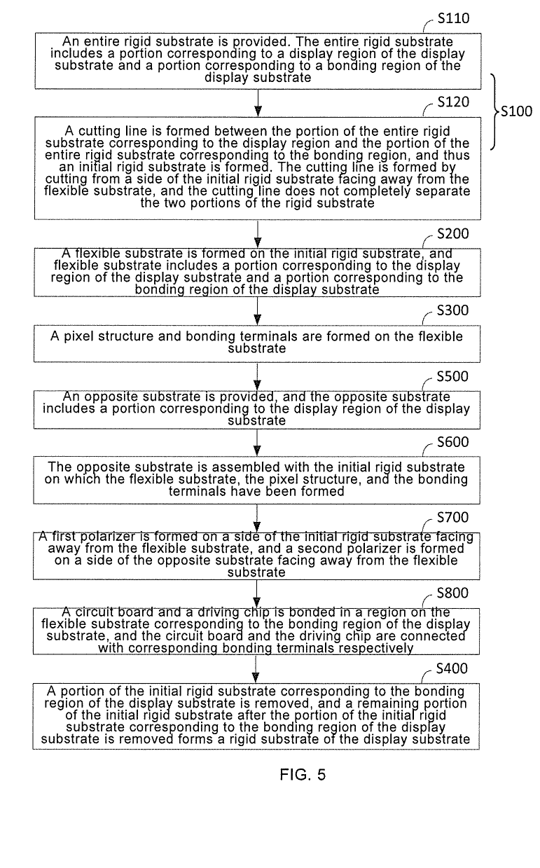

Referring to FIG. 5 and FIG. 6, in some embodiments, S100 (i.e., an initial rigid substrate is provided) includes the following steps 110-120 (S110-S120).

In S110, an entire rigid substrate is provided. The entire rigid substrate includes a portion corresponding to a display region of the display substrate and a portion corresponding to a bonding region of the display substrate.

For example, referring to FIG. 6, the entire rigid substrate 132 includes a portion corresponding to the display region 11 of the display substrate 10 and a portion corresponding to the bonding region 12 of the display substrate 10, and there is no cutting line 133 or the like on the entire rigid substrate 132.

In S120, a cutting line 133 is formed between the portion of the entire rigid substrate 132 corresponding to the display region 11 and the portion of the entire rigid substrate 132 corresponding to the bonding region 12, and thus an initial rigid substrate 131 is formed. The cutting line 133 is formed by cutting from a side of the initial rigid substrate 131 facing away from the flexible substrate 14, and the cutting line 133 does not completely separate the two portions of the rigid substrate 132 (that is the portion corresponding to the display region 11 and the portion corresponding to the bonding region 12).

For example, referring to FIG. 6, a cut is made upwardly from the bottom surface of the entire rigid substrate 132 to a certain depth. In FIG. 6, a portion of the entire rigid substrate 132 near the upper surface of the rigid substrate 132 in the vertical direction remains uncut. In this way, the cutting line 133 is formed. The cutting line 133 is disposed between the portion of the entire rigid substrate 132 corresponding to the display region 11 and the portion of the entire rigid substrate 132 corresponding to the bonding region 12. The cut of the cutting line 133 is disposed on the lower surface of the entire rigid substrate 132 in FIG. 6. After the cutting line 133 is formed, the preparation of the initial rigid substrate 131 is completed.

The cutting line 133 is previously formed on the entire rigid substrate 132 in order to form the initial rigid substrate 131. That is, a cutting line 133 is provided between a portion of the initial rigid substrate 131 corresponding to the display region 11 and a portion of the initial rigid substrate 131 corresponding to the bonding region 12. When S400 (i.e., removing the portion of the initial rigid substrate 131 corresponding to the bonding region 12 of the display substrate 10) is performed, the portion of the initial rigid substrate 131 corresponding to the bonding region 12 of the display substrate 10 may be directly removed along the cutting line 133. This removal step is convenient to prevent the flexible film 14 and the functional film layers on the flexible substrate 14 from being affected when the portion of the initial rigid substrate 131 corresponding to the bonding region 12 of the display substrate 10 is removed.

Referring to FIGS. 4 to 6, before S400 (i.e., removing the portion of the initial rigid substrate corresponding to the bonding region of the display substrate), the method for manufacturing the display substrate further includes the following steps 500 and 600 (S500 and S600).

In S500, an opposite substrate is provided. The opposite substrate includes a portion corresponding to the display region of the display substrate.

For example, the opposite substrate 17 is a color film substrate, and in some embodiments, the step of providing the opposite substrate 17 includes: providing a base substrate and forming a black matrix and a color filter layer on the base substrate. In some embodiments, the step of providing the opposite substrate 17 further includes: forming a common electrode on the base substrate. In some embodiments, the opposite substrate 17 is a base substrate that does not include any functional film layer.

In S600, the opposite substrate is assembled with the initial rigid substrate on which the flexible substrate, the pixel structure, and the bonding terminals have been formed.

For example, referring to FIG. 6, the opposite substrate 17 is assembled with the initial rigid substrate 131 on which the flexible substrate 14, the pixel structure 15, and the bonding terminals 16 have been formed. The flexible substrate 14, the pixel structure 15, and the bonding terminals 16 are all disposed between the opposite substrate 17 and the initial rigid substrate 131. In some embodiments, a liquid crystal layer is filled between the opposite substrate 17 and the initial rigid substrate 131.

Referring to FIG. 4 to FIG. 6, before S400 and after S600, the method for manufacturing the display substrate further includes the following steps 700-800 (S700-S800).

In S700, a first polarizer is formed on a side of the initial rigid substrate facing away from the flexible substrate, and a second polarizer is formed on a side of the opposite substrate facing away from the flexible substrate.

In S800, a circuit board and a driving chip is bonded in a region on the flexible substrate corresponding to the bonding region of the display substrate. The circuit board and the driving chip are connected with corresponding bonding terminals respectively.

It is worth mentioning that the order of S500 and S100 to S300 can be determined based on actual conditions. For example, in some embodiments, S500 is performed first, followed by S100 to S300. In some other embodiments, S100 to S300 are performed first, followed by S500. In some other embodiments, S500 is performed simultaneously with S100 to S300.

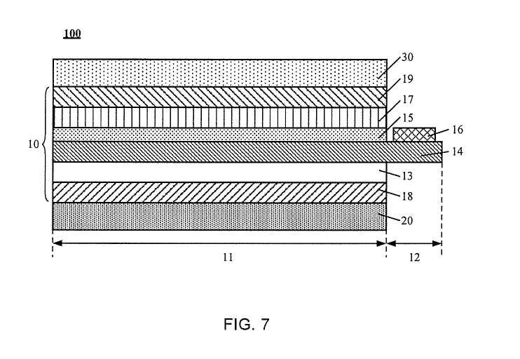

Referring to FIG. 7, some embodiments of the present disclosure provide a display device 100, and the display device 100 includes the display substrate 10 as described in any one of the above embodiments. The display device 100 further includes a backlight module 20 and a cover plate 30. The backlight module 20 is disposed on a side of the rigid substrate 13 of the display substrate 10 facing away from the flexible substrate 14 of the display substrate 10. The cover plate 30 is disposed on a side of the flexible substrate 14 facing away from the rigid substrate 13.

For example, the backlight module 20 is disposed on the side of the rigid substrate 13 of the display substrate 10 facing away from the flexible substrate 14 of the display substrate 10. That is, the backlight module 20 is disposed on the back side of the display substrate 10, and the backlight module 20 is configured to provide backlight for the display of the display substrate 10. The cover plate 30 is disposed on the side of the flexible substrate 14 facing away from the rigid substrate 13. For example, the cover plate 30 is disposed on a side of the opposite substrate 17 facing away from the rigid substrate 13, that is, the cover plate 30 is disposed on the display side of the display substrate 10. The cover plate 30 is configured to protect the display substrate 10.

The display device has the same advantages as the display substrate described above with respect to the related art, which will not be described here.

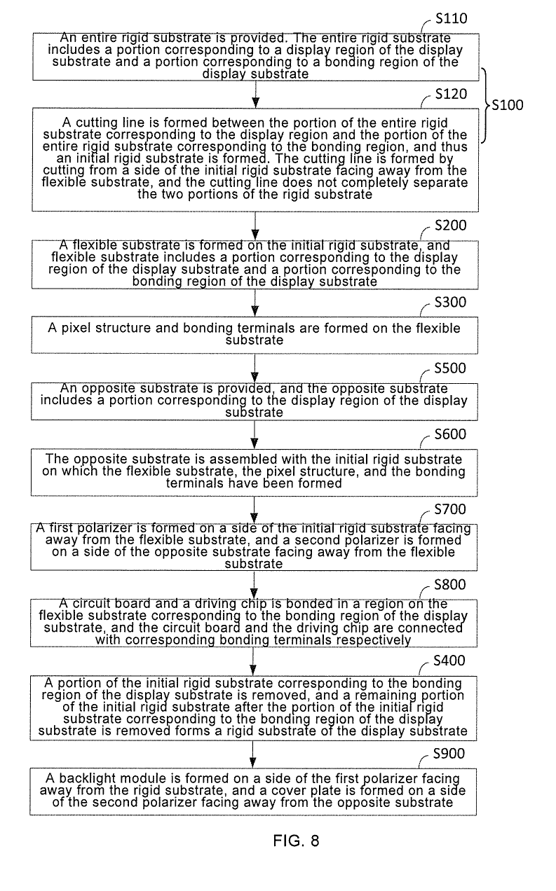

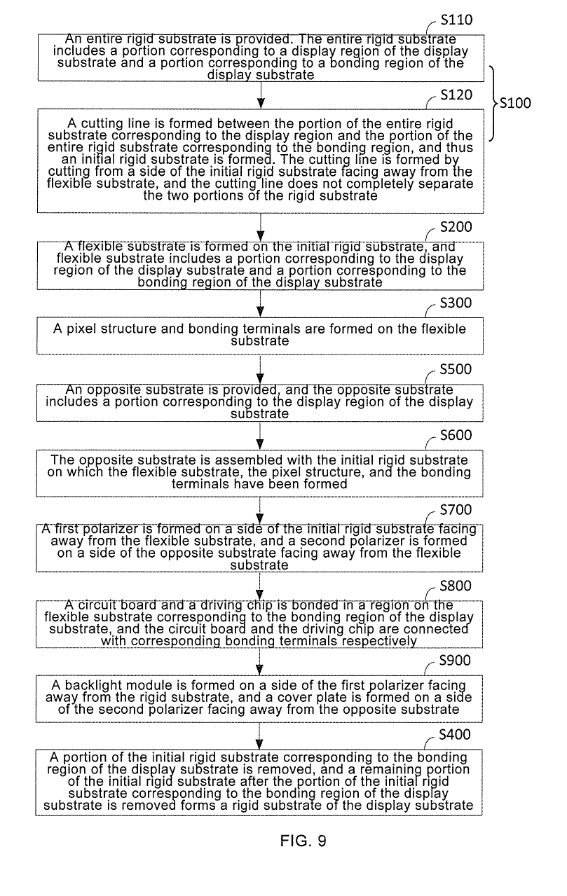

Referring to FIG. 8 or FIG. 9, some embodiments of the present disclosure provide a method for manufacturing a display device, which is applied to manufacture the display device as described in any one of the above embodiments. The method for manufacturing the display device includes the method for manufacturing the display substrate as described in any one of the above embodiments, and forming a backlight module and a cover plate.

For example, referring to FIG. 8, in some embodiments, the method for manufacturing the display device includes:

In S100, an initial rigid substrate is provided, as shown in FIG. 6. The initial rigid substrate includes a portion corresponding to a display region of the display substrate and a portion corresponding to a bonding region of the display substrate.

In S200, a flexible substrate is formed on the initial rigid substrate, as shown in FIG. 6. The flexible substrate includes a portion corresponding to the display region of the display substrate and a portion corresponding to the bonding region of the display substrate.

In S300, a pixel structure and bonding terminals are formed on the flexible substrate, as shown in FIG. 6.

In S500, an opposite substrate is provided, as shown in FIG. 6. The opposite substrate includes a portion corresponding to the display region of the display substrate.

In S600, the opposite substrate is assembled with the initial rigid substrate on which the flexible substrate, the pixel structure, and the bonding terminals have been formed, as shown in FIG. 6.

In S700, a first polarizer is formed on a side of the initial rigid substrate facing away from the flexible substrate, and a second polarizer is formed on a side of the opposite substrate facing away from the flexible substrate, as shown in FIG. 6.

In S800, a circuit board and a driving chip are bonded in a region of the flexible substrate corresponds to the bonding region of the display substrate, as shown in FIG. 6. Both the circuit board and the driving chip are connected to the bonding terminals, respectively.

In S400, a portion of the initial rigid substrate corresponding to the bonding region of the display substrate is removed, as shown in FIG. 6. A remaining portion of the initial rigid substrate after the portion corresponding to the bonding region of the display substrate is removed forms a rigid substrate of the display substrate.

In S900, a backlight module is formed on a side of the first polarizer facing away from the rigid substrate, and a cover plate is formed on a side of the second polarizer facing away from the opposite substrate, as shown in FIG. 7.

Alternatively, referring to FIG. 9, in some embodiments, the method for manufacturing the display device includes the following steps.

In S100, an initial rigid substrate is provided, as shown in FIG. 6. The initial rigid substrate includes a portion corresponding to a display region of the display substrate and a portion corresponding to a bonding region of the display substrate.

In S200, a flexible substrate is formed on the initial rigid substrate, as shown in FIG. 6. The flexible substrate includes a portion corresponding to the display region of the display substrate and a portion corresponding to the bonding region of the display substrate.

In S300, a pixel structure and bonding terminals are formed on the flexible substrate, as shown in FIG. 6.

In S500, an opposite substrate is provided, as shown in FIG. 6. The opposite substrate includes a portion corresponding to the display region of the display substrate.

In S600, the opposite substrate is assembled with the initial rigid substrate on which the flexible substrate, the pixel structure, and the bonding terminals have been formed, as shown in FIG. 6.

In S700, a first polarizer is formed on a side of the initial rigid substrate facing away from the flexible substrate, and a second polarizer is formed on a side of the opposite substrate facing away from the flexible substrate, as shown in FIG. 6.

In S800, a circuit board and a driving chip are bonded in a region of the flexible substrate corresponding to the bonding region of the display substrate, as shown in FIGS. 6, 11 and 12. Both the circuit board and the driving chip are connected to the bonding terminals, respectively.

In S900, a backlight module is formed on a side of the first polarizer facing away from the rigid substrate, and a cover plate is formed on a side of the second polarizer facing away from the opposite substrate, as shown in FIG. 6.

In S400, a portion of the initial rigid substrate corresponding to the bonding region of the display substrate is removed. A remaining portion of the initial rigid substrate after the portion of the initial rigid substrate corresponding to the bonding region of the display substrate is removed forms a rigid substrate of the display substrate.

The difference between the method for manufacturing the display device shown in FIG. 8 and the method for manufacturing the display device shown in FIG. 9 is only the order of the step of removing the portion of the initial rigid substrate corresponding to the bonding region of the display substrate and the step of forming the backlight module and the cover plate. In some embodiments, the sequence shown in FIG. 9 is adopted, that is to first form the backlight module and the cover plate and then remove the portion of the initial rigid substrate corresponding to the bonding region of the display substrate, thereby preventing a situation that the lines formed on the flexible substrate is broken due to the premature suspending of the portion of the flexible substrate corresponding to the bonding region.

The method for manufacturing the display device has the same advantages as the display device described above with respect to the related art, which will not be described here.

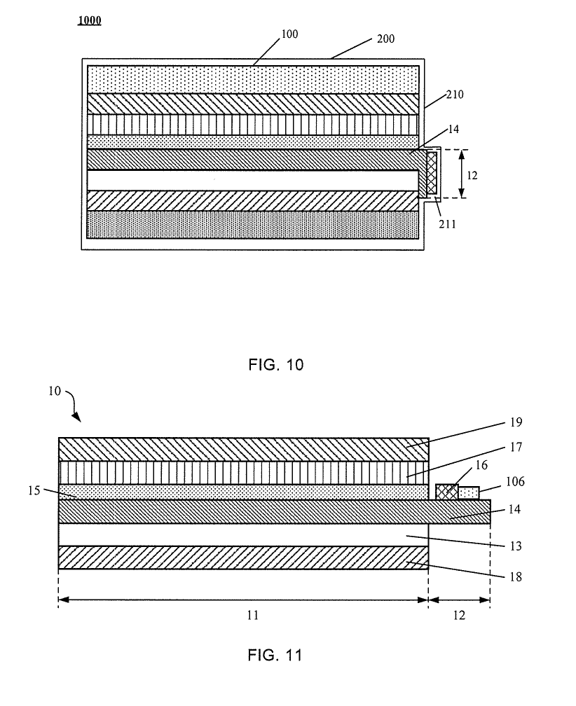

Referring to FIG. 10, some embodiments of the present disclosure provide a mobile terminal 1000, and the mobile terminal 1000 includes the display device 100 according to any one of the embodiments described above. The mobile terminal 1000 further includes a housing 200. The housing 200 includes a sidewall 210 corresponding to a portion of the flexible substrate of the display substrate in the display device corresponding to the bonding region of the display substrate. The sidewall is provided with a groove 211, and the portion of the flexible substrate corresponding to the bonding region of the display substrate is bent in the groove 211.

The advantages of the mobile terminal and the display device described above with respect to the prior art are the same, and will not be repeated here.

It is worth mentioning that the portion of the flexible substrate corresponding to the bonding region of the display substrate is bent in the groove, that is, the suspended portion of the flexible substrate is received in the groove, which may reduce the area of the mobile terminal occupied by the portion of the flexible substrate corresponding to the bonding region of the display substrate thereby increasing the screen-ratio of the mobile terminal. At the same time, the side wall of the housing may fix and support the portion of the flexible substrate corresponding to the bonding region of the display substrate.

In the above description of the embodiments, specific features, structures, materials, or characteristics can be combined in any suitable manner in one or more embodiments or examples.

It can be understood that the above embodiments are merely illustrative embodiments for the purpose of illustrating the principles of the disclosure, but the disclosure is not limited thereto. It will be apparent to those skilled in the art that various changes and modifications can be made therein without departing from the spirit and essence of the disclosure, which are also considered to be within the scope of the disclosure.

What is claimed is:

1. A display substrate, comprising:
a rigid substrate, wherein the rigid substrate includes a portion corresponding to a display region of the display substrate;
a flexible substrate disposed on the rigid substrate, wherein the flexible substrate includes a portion corresponding to the display region of the display substrate and a portion corresponding to a bonding region of the display substrate, and the portion of the flexible substrate corresponding to the bonding region is bendable;
a pixel structure disposed in a region on the flexible substrate corresponding to the display region of the display substrate; and
bonding terminals disposed in a region on the flexible substrate corresponding to the bonding region of the display substrate.

2. The display substrate according to claim 1, further comprising:
an opposite substrate disposed on a side of the pixel structure facing away from the flexible substrate, wherein
the opposite substrate includes a portion corresponding to the display region of the display substrate.

3. The display substrate according to claim 2, further comprising:
a first polarizer disposed on a side of the rigid substrate facing away from the flexible substrate; and
a second polarizer disposed on a side of the opposite substrate facing away from the flexible substrate.

4. The display substrate according to claim 1, further comprising:
a circuit board bonded to one of the bonding terminals; and
a driving chip bonded to another one of the bonding terminals.

5. A method for manufacturing the display substrate according to claim 1, comprising:
providing an initial rigid substrate, wherein the initial rigid substrate includes a portion corresponding to a display region of the display substrate and a portion corresponding to a bonding region of the display substrate;
forming a flexible substrate on the initial rigid substrate, wherein the flexible substrate includes a portion corresponding to the display region of the display substrate and a portion corresponding to the bonding region of the display substrate, and the portion of the flexible substrate corresponding to the bonding region is bendable;
forming a pixel structure and bonding terminals on the flexible substrate, wherein the pixel structure is disposed in the display region, and the bonding terminals are disposed in the bonding region; and
removing the portion of the initial rigid substrate corresponding to the bonding region of the display substrate, wherein a remaining portion of the initial rigid substrate after the portion of the initial rigid substrate corresponding to the bonding region is removed forms a rigid substrate of the display substrate.

6. The method for manufacturing the display substrate according to claim 5, wherein providing the initial rigid substrate includes:
providing an entire rigid substrate, wherein the entire rigid substrate includes a portion corresponding to the display region of the display substrate and a portion corresponding to the bonding region of the display substrate; and
forming a cutting line between the portion of the entire rigid substrate corresponding to the display region and the portion of the entire rigid substrate corresponding to the bonding region, so as to form the initial rigid substrate, wherein the cutting line is formed by cutting from a side of the initial rigid substrate facing away from the flexible substrate, and the portion of the entire rigid substrate corresponding to the display region and the portion of the entire rigid substrate corresponding to the bonding region are partially connected.

7. The method for manufacturing the display substrate according to claim 5, wherein before removing the portion of the initial rigid substrate corresponding to the bonding region of the display substrate, the method further comprises:
providing an opposite substrate, wherein the opposite substrate includes a portion corresponding to the display region of the display substrate; and
assembling the opposite substrate with the initial rigid substrate on which the flexible substrate, the pixel structure, and the bonding terminals have been formed.

8. The method for manufacturing the display substrate according to claim 7, wherein before removing the portion of the initial rigid substrate corresponding to the bonding region of the display substrate, and after assembling the opposite substrate with the initial rigid substrate on which the flexible substrate, the pixel structure, and the bonding terminals have been formed, the method further comprises:
forming a first polarizer on a side of the initial rigid substrate facing away from the flexible substrate, and forming a second polarizer on a side of the opposite substrate facing away from the flexible substrate; and
bonding a circuit board and a driving chip in a region on the flexible substrate corresponding to the bonding region of the display substrate, wherein the circuit board and the driving chip are connected to the bonding terminals respectively.

9. A display device, comprising:
the display substrate according to claim 1;
a backlight module disposed on a side of the rigid substrate of the display substrate facing away from the flexible substrate; and
a cover plate disposed on a side of the flexible substrate facing away from the rigid substrate of the display substrate.

10. A method for manufacturing the display device according to claim 8, comprising:
applying the method for manufacturing the display substrate according to claim 5 to form a substrate, and
forming a backlight module and a cover plate.

11. The method for manufacturing the display device according to claim 10, wherein
forming the backlight module and the cover plate is performed before removing the portion of the initial rigid substrate corresponding to the bonding region of the display substrate.

12. A mobile terminal, comprising:
the display device according claim 9; and
a housing, wherein the housing includes a sidewall corresponding to a portion of the flexible substrate of the display substrate in the display device corresponding to the bonding region of the display substrate, the sidewall is provided with a groove, and the portion of the flexible substrate corresponding the bonding region of the display substrate is bent in the groove.
